(19) United States
(12) Patent Application Publication
(10) Pub. No.: US 2024/0405136 A1
(43) Pub. Date: Dec. 5, 2024

(54) SEMICONDUCTOR LIGHT RECEIVING DEVICE

(71) Applicant: Dexerials Corporation, Tochigi (JP)

(72) Inventors: Takatomo ISOMURA, Tochigi (JP); Etsuji OMURA, Tochigi (JP)

(73) Assignee: Dexerials Corporation, Tochigi (JP)

(21) Appl. No.: 18/776,181

(22) Filed: Jul. 17, 2024

Related U.S. Application Data
(63) Continuation of application No. PCT/JP2022/001752, filed on Jan. 19, 2022.

(51) Int. Cl. H01L 31/0232; H01L 31/0236; H01L 31/0304; H01L 31/105

(52) U.S. Cl. CPC H01L 31/02327; H01L 31/02366; H01L 31/03046; H01L 31/105

(57) ABSTRACT

A semiconductor light receiving device (1) has a light receiving portion (6) with a light absorbing layer (4) on a first surface (2a) side of a semiconductor substrate (2) transparent to incident light in an infrared range for optical communications, a reflecting portion (11) in a region where light that was incident on the light receiving portion (6) and passed through the light absorbing layer (4) is reached on a second surface (2b) side opposite the first surface (2a) to reflect the light toward the second surface (2b), and end surfaces (2c, 2d) of the semiconductor substrate (2), where light reflected by the reflecting portion (11) and reflected by the second surface (2b) reaches, are formed as a rough surface having roughness with a height equal to or greater than the wavelength of the incident light.

### CROSS-REFERENCE TO RELATED APPLICATION

This application is a continuation of the International PCT application serial no. PCT/JP2022/001752, filed on Jan. 19, 2022. The entirety of the above-mentioned patent application is hereby incorporated by reference herein and made a part of this specification.

### TECHNICAL FIELD

This invention relates to semiconductor light receiving devices that receive infrared light used in optical measurement and optical communications, and in particular, to semiconductor light receiving devices with improved falling response characteristics after receiving an optical pulse.

### BACKGROUND ART

Optical pulse testers (Optical Time Domain Reflectometer: OTDR) have been widely used to measure the loss state and defect location of optical fiber cables used for optical communications. This optical pulse tester inputs pulsed light from one end of a laid optical fiber cable and receives backscattered light back to the input side of the Rayleigh scattered light generated when this pulsed light travels in the optical fiber cable. Then, the loss is measured based on the amount (intensity) of backscattered light, and the distance from the optical pulse tester is measured based on the time from the input of the pulsed light until the backscattered light is received.

At the junction point where the optical pulse tester is connected to one end of the optical fiber cable to be measured, a Fresnel reflection is inevitable when the pulsed light enters the optical fiber cable. Therefore, when pulsed light is emitted from the optical pulse tester, the Fresnel reflection light at this junction point is first received by the optical pulse tester, and then the backscattered light is received.

The light intensity of this backscattered light is extremely low compared to the Fresnel reflected light. Therefore, a light receiving device of the optical pulse tester cannot detect the backscattered light until a time for receiving the Fresnel reflected light equivalent to the pulse width of the pulsed light and a response time (fall time) from the end of receiving the Fresnel reflected light to the timing capable of detecting the backscattered light has passed. As a result, even if a defect exists within the round-trip distance of the light from the optical pulse tester in the time when the backscattered light cannot be detected, there is a dead zone in which this defect cannot be detected.

In order to reduce the dead zone, it is required to shorten the fall time of the light receiving device. For example, as shown in Patent Document #1,a semiconductor light receiving device is known in which light transmitted through the first light absorbing layer of the light receiving part is absorbed by the second light absorbing layer to reduce the light re-entering the first light absorbing layer in order to shorten the fall time of the light receiving device. Since less light is reflected and re-enters the first light absorbing layer, the photocurrent decreases rapidly when light finishes passing through the first light absorbing layer, and the fall time is shortened.

### PRIOR ART DOCUMENTS

### Patent Documents

Patent Document #1: Japanese Unexamined Patent Application Publication No. Hei 8-8456

### SUMMARY OF THE INVENTION

### Problems to be Solved by the Invention

The semiconductor light receiving device of Patent Document #1 has the first light absorbing layer for converting the incident light into a photocurrent (electrical signal) and the second light absorbing layer for absorbing the light passed through the first light absorbing layer so that the light does not re-enter the first light absorbing layer. As a result, its structure is complicated and the two light absorbing layers, which are not easy to form for crystal growth, should be formed separately, which increases the manufacturing cost.

The present invention provides a semiconductor light receiving device having a simple structure and configured to prevent light passed through the light absorbing layer of the light receiving portion from re-entering the light receiving portion.

### Means to Solve the Problems

The present invention presents a semiconductor light receiving device having a light receiving portion with a light absorbing layer on a first surface side of a semiconductor substrate that is transparent to incident light in an infrared range for optical communications; wherein a reflecting portion is provided on a second surface side of the semiconductor substrate opposite the first surface in a region where the incident light incident on the light receiving portion and passed through the light absorbing layer reaches, the reflecting portion reflecting the incident light toward the second surface, an end surface of the semiconductor substrate, where the light reflected by the reflecting portion and reached the second surface reaches by reflecting at the second surface, are formed as a rough surface having roughness with a height equal to or greater than a wavelength of the incident light.

According to the above configuration, the semiconductor light receiving device has the light receiving portion with the light absorbing layer on the first surface side of the semiconductor substrate, and receives light in the infrared light range used for optical communications. The second surface side of the semiconductor substrate is provided with the reflecting portion that reflects the incident light toward the second surface side of the semiconductor substrate in the region where the light incident on the light receiving portion and passed through the light absorbing layer reaches. The reflected light reflected by the reflecting portion is reflected by the second surface of the semiconductor substrate and reaches the end surface of the semiconductor substrate. Since the end surface of the semiconductor substrate is formed as a rough surface having roughness with a height equal to or greater than the wavelength of the incident light, most of the light that reaches this end surface is not reflected at the end surface. Therefore, it is possible to reduce the re-entering of the light that has entered the light receiving portion and passed through the light absorbing layer, and to shorten the fall time of the semiconductor light receiving device.

In a first preferable aspect of the present invention, the reflecting portion is formed as a V-shaped groove in cross section, in which the semiconductor substrate is recessed from the second surface side to the first surface side so as to have two flat reflecting surfaces.

According to this configuration, the groove depth can be made shallow while the groove length is long and the groove width is wide, so it is easy to form a large reflecting portion. This reflecting portion allows misalignment of the light-receiving position and reflects the incident light passed through the light absorbing layer toward the second surface of the semiconductor substrate. Therefore, it is possible to reduce the re-entering of light that has entered the light receiving portion and passed through the light absorbing layer into the light receiving portion.

In a second preferable aspect of the present invention, the second surface is a (100) surface of the semiconductor substrate, and a reflecting surface of the reflecting portion is a (111) surface of the semiconductor substrate.

According to this configuration, the reflecting surface of the reflecting portion is flat and the inclination angle of the reflecting surface is constant. Since the reflecting surface of the reflecting portion is flat, it is possible to prevent the incident light that is incident on the light receiving portion and passed through the light absorbing layer from being scattered by the reflecting portion so as to return to the light receiving portion. Furthermore, since the inclination angle of the reflecting surface is constant, the light incident on the light receiving portion and passed through the light absorbing layer can be surely reflected toward the second surface of the semiconductor substrate. Therefore, it is possible to further reduce the re-entering of light that has entered the light receiving portion and passed through the light absorbing layer into the light receiving portion.

In a third preferable aspect of the present invention, the second surface is formed as a rough surface having roughness with a height equal to or greater than the wavelength of the incident light.

According to this configuration, since the second surface of the semiconductor substrate is a rough surface, the reflection of light reflected by the reflecting portion and reached the second surface of the semiconductor substrate can be reduced, so that light reflected at the end surface of the semiconductor substrate can be further reduced. Therefore, it is possible to further reduce the re-entering of light that has entered the light receiving portion and passed through the light absorbing layer into the light receiving portion.

### Advantages of the Invention

According to the semiconductor light receiving device of the present invention, it is possible to prevent light that has passed through the light absorbing layer of the light receiving part from re-entering the light receiving portion with a simple structure.

### BRIEF DESCRIPTION OF THE DRAWINGS

FIG. 1 is a perspective view of a semiconductor light receiving device according to an embodiment of the present invention;

FIG. 2 is a plan view of the semiconductor light receiving device of FIG. 1 as viewed from the light incident side;

FIG. 3 is a cross-sectional view taken along III-III line in FIG. 2;

FIG. 4 is a cross-sectional model diagram of a micro texture formed on an end surface of a semiconductor substrate;

FIG. 5 is a graph showing reflectance due to the micro texture;

FIG. 6 is a diagram showing an example of rays of light incident on the light receiving portion;

FIG. 7 is a diagram showing an example of light reflection when the second surface of the semiconductor substrate is also formed to be a rough surface; and

FIG. 8 is a diagram showing a modified example of a semiconductor light receiving device.

### DESCRIPTION OF EMBODIMENTS

The following is a description of the form in which the invention is implemented, based on embodiment.

### EMBODIMENT

The semiconductor light receiving device 1 has a PIN photodiode or avalanche photodiode, for example, that receives incident light in an infrared light range for optical communications (wavelength λ in the range of 1100 to 1600 nm). Here, an example of a semiconductor light receiving device 1 with a PIN photodiode is described.

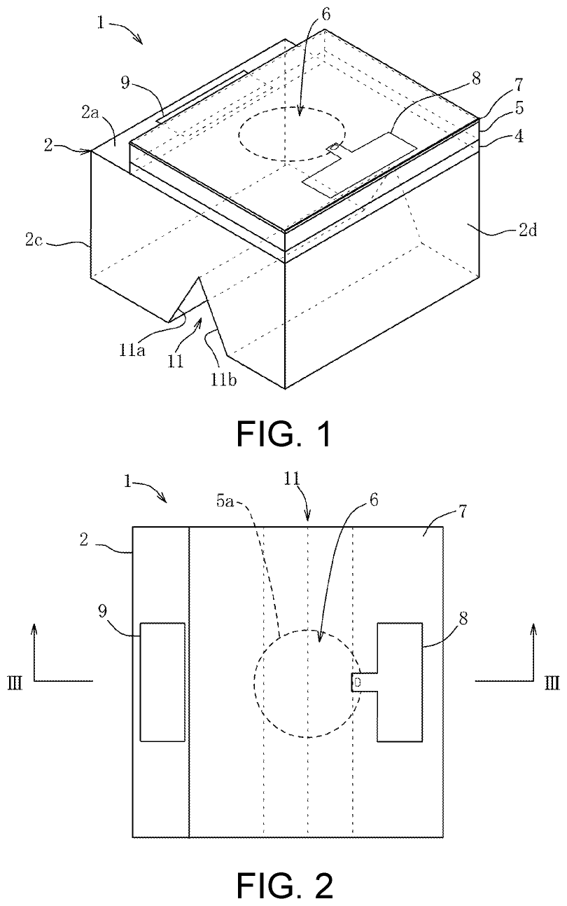

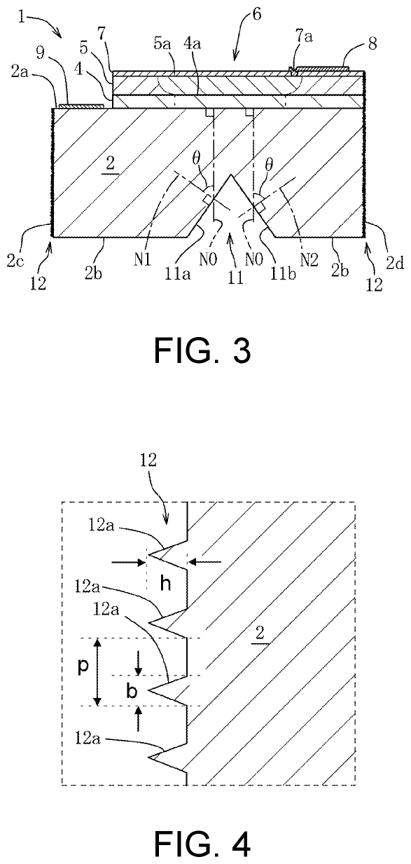

As shown in FIGS. 1 to 3, semiconductor light receiving device 1 has, for example, an n-InP substrate as a single-crystal semiconductor substrate 2 that is transparent to incident light in the infrared light range for optical communications. A first surface 2a of the semiconductor substrate 2 is the (100) plane of the semiconductor substrate 2. On this first surface 2a, an InGaAs layer, for example, as the light absorbing layer 4 that absorbs incident light, and an n-InP layer as the semiconductor layer 5 are formed. The semiconductor layer 5 has a p-type diffusion region 5a selectively doped with, for example, Zn. The region of the light absorbing layer 4 that contacts the p-type diffusion region 5a is the light absorbing region 4a, and the p-type diffusion region 5a, the light absorbing region 4a, and the semiconductor substrate 2 form a PIN photodiode that is the light receiving portion 6. The thicknesses of the semiconductor layer 5 and the light absorbing layer 4 are appropriately set, and are formed to be thickness of, for example, 0.5 to 5 μm.

The surface of the semiconductor layer 5 is covered with a protective film 7 (e.g., a SiN film, a SiON film, etc.) having an opening 7a that is connected to the p-type diffusion region 5a. The protective film 7 may have an anti-reflection function for light incident on the light receiving portion. An anode electrode 8 is formed to connect to the p-type diffusion region 5a through the opening 7a. The opening 7a may be formed inside the inner edge of the p-type diffusion region 5a, exposing the p-type diffusion region 5a.

The size and shape of the p-type diffusion region 5a are appropriately set, and for example, it is formed in a circular shape with a diameter of 10 to 200 μm. A cathode electrode 9 connected to the first surface 2a of the semiconductor substrate 2 is formed in the exposed portion of the first surface 2a. The anode electrode 8 and the cathode electrode 9 are formed by selectively depositing a metal film containing, for example, chromium or gold. The photocurrent photoelectrically converted in the light receiving portion 6 is output to the outside through the anode electrode 8 and the cathode electrode 9.

The second surface 2b side (back side), which is opposite the first surface 2a of the semiconductor substrate 2, is provided with a reflecting portion 11 in the region where light incident from the outside to the light receiving portion 6 so as to be incident from the first surface 2a side to the semiconductor substrate 2 and passing through the light absorbing region 4a of the light absorbing layer 4 reaches. The reflecting portion 11 reflects the light that has passed through the light absorbing layer 4 of the light receiving portion 6 toward the second surface 2b of the semiconductor substrate 2.

The reflecting portion 11 is formed in a V-shaped groove in cross section by recessing the semiconductor substrate 2 from the second surface 2b side toward the first surface 2a side so as to have two flat reflecting surfaces 11a, 11b. The width of this groove is formed to be equal to or greater than the diameter of the light receiving portion 6, and a metal film containing, for example, gold may be formed as a reflecting film within the groove. Since the groove is V-shaped in cross section, it is easy to form a large reflecting portion 11.

The reflecting surfaces 11a and 11b are formed so that a normal N1 to the reflecting surface 11a and a normal N2 to the reflecting surface 11b intersect at an angle θ greater than 45° with respect to a normal NO to the first surface 2a of the semiconductor substrate 2. This allows the light incident on the light receiving portion 6 and transmitted through the light absorbing layer 4 to be reflected toward the second surface 2b of the semiconductor substrate 2.

The V-shaped groove in cross section is formed by known anisotropic etching using, for example, a bromine-methanol solution as a known etching solution having anisotropy in which the etching rate depends on the crystal plane orientation. Specifically, an etching mask layer is formed on the second surface 2b of the semiconductor substrate 2, and the exposed portion of the second surface 2b is anisotropically etched to expose the (111) surface of the semiconductor substrate 2, which has a slower etching rate. This forms two reflective surfaces 11a and 11b, which are the (111) surfaces of the semiconductor substrate 2.

Since the (100) and (111) planes of the semiconductor substrate 2 intersect at an angle of 54.7°, the normals N1 and N2 of the reflecting surfaces 11a and 11b intersect with the normal NO of the first surface 2a at an angle θ=54.7° respectively. The V-shaped groove in cross section can also be formed by, for example, etching with an ion beam so that the angle θ is greater than 45°.

Among the four end surfaces of the semiconductor substrate 2, the two end surfaces 2c and 2d, facing the reflective surfaces 11a and 11b respectively, are rough surfaces formed with a micro texture 12 consisting of minute roughness. The micro texture 12 acts to continuously change the refractive index between the semiconductor substrate 2 and the air, thereby reducing the reflection of light at the end surfaces 2c and 2d.

FIG. 4 shows a cross-sectional model of the micro texture 12. The micro texture 12 is formed by physically processing the semiconductor substrate 2, and has a plurality of minute protrusions 12a that are shaped like triangles in cross section. The height of the protrusions 12a of the micro texture 12 is h, the width of the base end of the protrusions 12a is b, and the arrangement pitch of the protrusions 12a is p, and the average values of these are the average height H, average width B, and average pitch P, respectively.

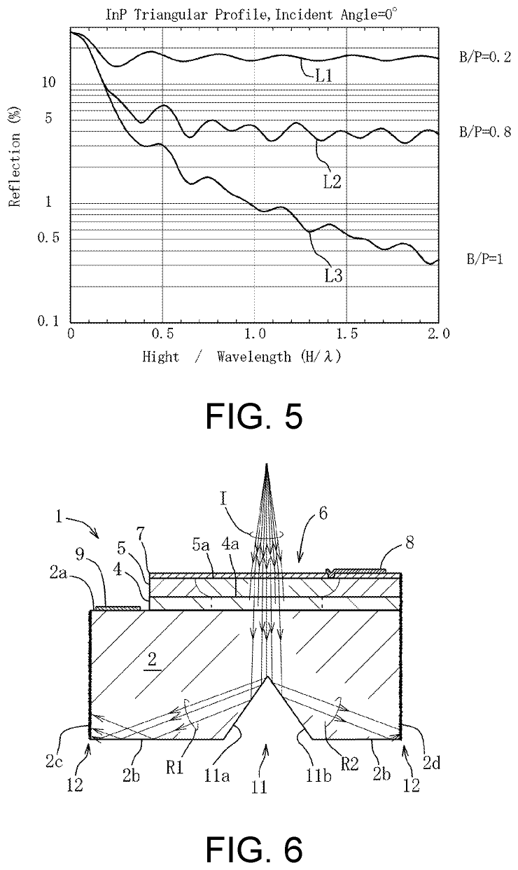

FIG. 5 shows the simulation results of the reflectance of the end surface 2c having the micro texture 12 of FIG. 4. The relationship between the ratio of the average height H of the plurality of protrusions 12a to the wavelength λ of the incident light (H/λ) and the reflectance is shown by curves L1 to L3 for each density of the plurality of protrusions 12a on the cross-section of the end surface 2c. The density of the plurality of protrusions 12a is represented by the ratio of the average width B of the plurality of protrusions 19a to the average pitch P of the plurality of protrusions 12a (B/P). Curve L1 corresponds to B/P=0.2, curve L2 corresponds to B/P=0.8, and curve L3 corresponds to B/P=1.

In the case of a flat end surface 2c without any protrusions 12a (average height H=0, i.e. H/λ=0), the reflectance is 27.4%, but the reflectance tends to decrease as the ratio (H/A) of the average height H of the protrusions 12a to the wavelength λ increases. Also, the larger the density of the plurality of protrusions 12a (B/P), the smaller the reflectance. Although the incident light is assumed to be incident perpendicular to the end surface 2c, the above trend does not change significantly even if the angle of incidence is changed.

According to FIG. 5, if the ratio of the average height H of the plurality of protrusions 12a to the wavelength λ(H/A) is 1 or more (the average height H of the plurality of protrusions 12a is equal to or greater than the wavelength λ) and the density of the plurality of protrusions 12a (B/P) is 0.8 or more, the reflectance can be reduced to 5% or less. When the density of the multiple protrusions 12a (B/P) shown by curve L3 is 1, the reflectance can be reduced to 1% or less when the ratio of the average height H of the plurality of protrusions 12a to the wavelength λ(H/λ) is 1 or more.

In order to reduce the reflectance in this manner, the micro texture 12 with a plurality of protrusions 12a are formed on the end surfaces 2c and 2d of the semiconductor substrate 2, having the average height H greater than the wavelength of the incident light λ and the density (B/P) of 0.8 or greater, preferably with the density (B/P) of 1. If the portion between the plurality of protrusions 12a is considered as a groove, using the depth of the groove, the width of the groove bottom, and the pitch of the groove in the same manner as above, it can be said that the groove has an average depth equal to or greater than the wavelength λ of the incident light and the proportion of the width of the groove bottom in the cross section of micro texture 12 is less than 20%.

The micro texture 12 is formed, for example, when the semiconductor substrate 2 in the form of a wafer attached to a support film is ground and divided by a dicing blade. When abrasive grains with a grain diameter larger than the wavelength λ of the incident light are fixed to the dicing blade, it is possible to form protrusions 12a with a height equal to or greater than the wavelength λ of incident light. Processing conditions such as the rotation speed and movement speed of the dicing blade are appropriately selected. The micro texture 12 may also be formed on end surfaces other than the end surfaces 2c and 2d.

As shown in FIG. 6 incident light I is incident on the light receiving portion 6 from outside the semiconductor light receiving device 1 perpendicular to the first surface 2a of the semiconductor substrate 2. The incident light I spreads out in a cone shape with a vertex angle of, for example, about 14° and travels through the air. A portion of the incident light I incident on the light receiving portion 6 is photoelectrically converted in the light receiving portion 6, and light that is not photoelectrically converted passes through the light absorbing layer 4 (light absorbing region 4a) to reach the reflecting portion 11.

Light that reaches the reflecting portion 11 of the incident light I is reflected by the reflecting surfaces 11a, 11b toward the second surface 2b of the semiconductor substrate 2. The reflected light R1 reflected by the reflecting surface 11a is reflected by the second surface 2b of the semiconductor substrate 2 and reaches the end surface 2c. Since the micro texture 12 is formed on the end surface 2c, most of the reflected light R1 is not reflected at the end surface 2c and goes out of the semiconductor light receiving device 1, so it does not re-enter the light absorbing layer 4 (light absorbing area 4a) of the light receiving portion 6 from the semiconductor substrate 2 side.

Similarly, reflected light R2 reflected by reflecting surface 11b is reflected by the second surface 2b and reaches end surface 2d on which micro texture 12 is formed, so that most of reflected light R2 does not re-enter the light-receiving unit 6. Even if some of reflected light R1, R2 reflected by reflecting portion 11 toward second surface 2b directly reaches end surfaces 2c, 2d having micro texture 12 without being reflected by second surface 2b, it is hardly reflected by the end surfaces 2c, 2d, thus reducing the re-entering to the light receiving portion 6.

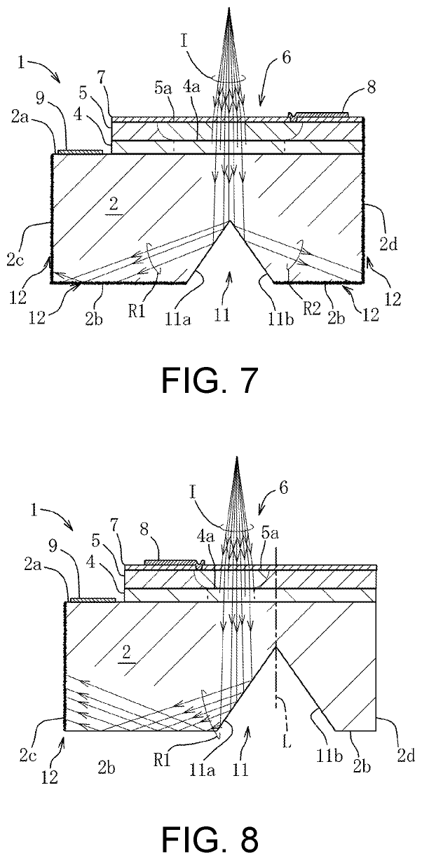

As shown in FIG. 7, a micro texture 12 similar to the micro texture 12 on the end surfaces 2c, 2d of the semiconductor substrate 2 may also be formed on the second surface 2b of the semiconductor substrate 2. The micro texture 12 on the second surface 2b of the semiconductor substrate 2 can be formed, for example, by polishing the second surface 2b with an abrasive containing abrasive grains with a grain diameter larger than the wavelength λ. Since reflection on the second surface 2b of the semiconductor substrate 2 is reduced, reflected light R1, R2 re-entering the light receiving portion 6 is further reduced.

As shown in FIG. 8, light that has passed through the light absorbing layer 4 of the light receiving portion 6 of the incident light I may be reflected toward the second surface 2b of the semiconductor substrate 2 only by the reflecting surface 11a of the reflecting portion 11. The reflected light R1 reflected by the reflecting surface 11a is reflected by the second surface 2b and reaches the end surface 2c on which the micro texture 12 is formed, thus reducing the re-entering to the light receiving portion 6.

It is also possible to downsize the semiconductor light receiving device 1 by dividing it along a straight-line L at the intersection of the reflective surfaces 11a and 11b. Although the figure is omitted, it is also possible to form the semiconductor light receiving device 1 symmetrically with respect to one V-shaped groove by forming an end surface with light receiving portion 6, anode electrode 8, cathode electrode 9, and micro texture 12 on the semiconductor substrate 2 on the reflecting portion 11b side that is divided by straight line L as well.

The operation and effects of the semiconductor light receiving device 1 will be described. The semiconductor light receiving device 1 has the light receiving portion 6 having the light absorbing layer 4 on the first surface 2a side of the semiconductor substrate 2, which receives light in the wavelength range used for optical communications (2=1100 to 1600 nm) and outputs a photocurrent by photoelectric conversion. On the second surface 2b side of the semiconductor substrate 2, in the region where the light passed through the light absorbing layer 4 (light absorbing region 4a) of the incident light I incident on the light receiving section 6 reaches, there is a reflecting portion 11 that reflects the light toward the second surface 2b of the semiconductor substrate 2.

The reflected light R1, R2 reflected by the reflecting portion 11 is reflected by the second surface 2b and reaches the end surfaces 2c, 2d of the semiconductor substrate 2. Since the end surfaces 2c, 2d of the semiconductor substrate 2 are formed to be rough surfaces with roughness of a height equal to or greater than the wavelength of the incident light I, most of the reflected light R1, R2 that reaches these end surfaces 2c, 2d is not reflected by the end surfaces 2c, 2d and goes out of the semiconductor light receiving device 1. Therefore, it is possible to reduce the re-entering into the light receiving portion 6 of light that has entered the light receiving portion 6 and passed through the light absorbing layer 4, and to shorten the fall time of the semiconductor light receiving device 1.

The reflecting portion 11 is formed in the V-shaped groove recessed from the second surface 2b side of the semiconductor substrate 2 toward the first surface 2a side so as to have two flat reflecting surfaces 11a, 11b. This allows the groove length to be long and the groove width to be wide while the groove depth to be shallow, so it is easy to form the large reflecting portion 11. This reflecting portion 11 allows misalignment of the light-receiving position and reflects the light passed through the light absorbing layer 4 of the light receiving portion 6 toward the second surface 2b of the semiconductor substrate 2, and further reduces the re-entering of the light passed through the light absorbing layer 4 into the light receiving portion 6.

Since the second surface 2b of the semiconductor substrate 2 is the (100) surface of this semiconductor substrate 2 and the reflecting surfaces 11a, 11b of the reflecting portion 11 are the (111) surfaces of the semiconductor substrate 2, the reflecting surfaces 11a, 11b become flat and the inclination angle of the reflecting surfaces 11a, 11b is constant. Therefore, it can be prevented that the light passed through the light absorbing layer 4 of the incident light I is scattered by the reflecting portion 11 so that it returns to the light receiving portion 6. In addition, since the inclination angle of the reflecting surfaces 11a and 11b is constant, the light incident on the light receiving portion 6 and transmitted through the light absorbing layer 4 can be surely reflected toward the second surface 2b of the semiconductor substrate 2. Therefore, it is possible to further reduce the re-entering into the light receiving portion 6 of the light passed through the light absorbing layer 4 of the light receiving portion 6.

When the second surface 2b of the semiconductor substrate 2 is the rough surface having roughness with the depth equal to or greater than the wavelength of the incident light I, the reflection of the reflected light R1, R2 that is reflected by the reflecting portion 11 and reaches the second surface 2b can be reduced. Therefore, the reflected light R1, R2 reaching the end surfaces 2c, 2d of the semiconductor substrate 2 is reduced, and the light reflected at the end surfaces 2c, 2d can be further reduced, thus further reducing the re-entering to the light receiving portion 6 of the light that has entered the light receiving portion 6 and passed through the light absorbing layer 4.

The length of the V-shaped groove in cross section where the reflecting portion 11 is formed may be formed equal to the size of the light receiving portion 6. The light receiving portion 6 may be, for example, an avalanche photodiode with a multiplication layer, or a photodiode formed with a different material and a different shape from those described above. Other forms can be implemented by those skilled in the art by adding various changes to the above embodiment without departing from the purpose of the invention, and the present invention includes such kinds of modified forms.

1. A semiconductor light receiving device having a light receiving portion with a light absorbing layer on a first surface side of a semiconductor substrate that is transparent to incident light in an infrared range for optical communications; wherein
a reflecting portion is provided on a second surface side of the semiconductor substrate opposite the first surface in a region where the incident light incident on the light receiving portion and passed through the light absorbing layer reaches, the reflecting portion reflecting the incident light toward the second surface,
an end surface of the semiconductor substrate, where the light reflected by the reflecting portion and reached the second surface reaches by reflecting at the second surface, is formed as a rough surface having roughness with a height equal to or greater than a wavelength of the incident light.

2. The semiconductor light receiving device according to claim 1; wherein the reflecting portion is formed as a V-shaped groove in cross section, in which the semiconductor substrate is recessed from the second surface side to the first surface side so as to have two flat reflecting surfaces.

3. The semiconductor light receiving device according to claim 1; wherein the second surface is a (100) surface of the semiconductor substrate, and a reflecting surface of the reflecting portion is a (111) surface of the semiconductor substrate.

4. The semiconductor light receiving device according to claim 1; wherein the second surface is formed as a rough surface having roughness with a height equal to or greater than the wavelength of the incident light.
